(19) United States
(12) Patent Application Publication
(10) Pub. No.: US 2024/0222403 A1
(43) Pub. Date: Jul. 4, 2024

(54) IMAGE SENSING DEVICE AND METHOD FOR MANUFACTURING THE SAME

(71) Applicant: SK hynix Inc., Icheon-si (KR)

(72) Inventor: Sung Hoon JEON, Icheon-si (KR)

(21) Appl. No.: 18/460,008

(22) Filed: Sep. 1, 2023

(30) Foreign Application Priority Data
Jan. 3, 2023 (KR) 10-2023-0000637

(51) Int. Cl. H01L 27/146

(52) U.S. Cl. CPC H01L 27/14623; H01L 27/14621; H01L 27/14627; H01L 27/14645; H01L 27/14685

(57) ABSTRACT

An image sensing device includes a substrate layer configured to include an image pixel region and a dummy region disposed separately from the image pixel region; a first light shielding structure configured to cover the substrate layer of the dummy region to block light from being incident upon the substrate layer of the dummy region; a color filter layer disposed over the first light shielding structure; and a second light shielding structure configured to block reflected light from entering the image pixel region and disposed over the first light shielding structure, to the second light shielding structure extending from the first light shielding structure toward the color filter layer and having a predetermined height that allows the second light shielding structure to penetrate the color filter layer.

### CROSS-REFERENCE TO RELATED APPLICATION

This patent document claims the priority and benefits of Korean patent application No. 10-2023-0000637, filed on Jan. 3, 2023, which is incorporated by reference in its entirety as part of the disclosure of this patent document.

### TECHNICAL FIELD

The technology and implementations disclosed in this patent document generally relate to an image sensing device and a method for manufacturing the image sensing device.

### BACKGROUND

An image sensor is used in electronic devices and other devices or systems to capture and convert optical images into electrical signals. With the recent development of automotive, medical, computer and communication industries, the demand for highly integrated, higher-performance image sensors has been rapidly increasing in various electronic devices such as digital cameras, camcorders, personal communication systems (PCSs), video game consoles, surveillance cameras, medical micro-cameras, robots, etc.

### SUMMARY

Various embodiments of the disclosed technology relate to technology for preventing light reflected from a module or portion of an image sensing device from being introduced into an effective pixel region of the image sensing device.

In accordance with an embodiment of the disclosed technology, an image sensing device may include a substrate layer configured to include an image pixel region including image pixels including photoelectric conversion elements configured to produce image pixel signal by a photoelectric conversion of incident light and a dummy region disposed separately from the image pixel region; a first light shielding structure configured to cover the substrate layer of the dummy region and configured to block the incident light from being incident upon the substrate layer of the dummy region; a color filter layer disposed over the first light shielding structure; and a second light shielding structure configured to block reflected light from entering the image pixel region and disposed over the first light shielding structure, the second light shielding structure extending from the first light shielding structure toward the color filter layer and having a predetermined height that allows the second light shielding structure to penetrate the color filter layer.

In accordance with another embodiment of the disclosed technology, a method for manufacturing an image sensing device may include forming a substrate layer to include 1) an image pixel region including image pixels including photoelectric conversion elements configured to produce image pixel signals by a photoelectric conversion of incident light and 2) a dummy region surrounding the image pixel region; forming a first metal layer and a second metal layer over the substrate layer; forming a second light shielding structure in a boundary region between the image pixel region and the dummy region by patterning the second metal layer; patterning the first metal layer to form a grid structure in the image pixel region, and forming a first light shielding structure in the dummy region; forming a color filter layer over a region defined by the grid structure and over the first light shielding structure; and forming a lens layer over the color filter layer.

In accordance with another embodiment of the disclosed technology, a method for manufacturing an image sensing device may include forming a substrate layer to include 1) an image pixel region including image pixels including photoelectric conversion elements configured to produce image pixel signals by a photoelectric conversion of incident light and 2) a dummy region surrounding the image pixel region; forming a metal layer over the substrate layer; patterning the metal layer to form a grid structure in the image pixel region, and forming a first light shielding structure in the dummy region; forming a color filter layer over a region defined by the grid structure and over the first light shielding structure; forming a lens layer over the color filter layer; forming a trench by etching the lens layer and the color filter layer to expose the first light shielding structure; and forming a second light shielding structure by filling the trench with a light shielding material.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a schematic diagram illustrating an example of a planar structure of a pixel array of the image sensing device shown in FIG. 1 based on some implementations of the disclosed technology.

FIG. 3 is a cross-sectional view illustrating an example of the pixel array taken along the line X-X′ shown in FIG. 2 based on some implementations of the disclosed technology.

FIGS. 4A to 4D are cross-sectional views illustrating examples of methods for forming the structure shown in FIG. 3 based on some implementations of the disclosed technology.

FIG. 5 is a cross-sectional view illustrating another example of the pixel array taken along the line X-X′ shown in FIG. 2 based on some implementations of the disclosed technology.

FIGS. 6A to 6C are cross-sectional views examples of a method for forming a flare protection wall having the same shape as in FIG. 5 based on some implementations of the disclosed technology.

FIG. 7 is a cross-sectional view illustrating another example of the pixel array taken along the line X-X′ shown in FIG. 2 based on some implementations of the disclosed technology.

FIGS. 8A and 8B are cross-sectional views illustrating examples of a method for forming the structure shown in FIG. 7 based on some implementations of the disclosed technology.

### DETAILED DESCRIPTION

This patent document provides implementations and examples of an image sensing device and a method for manufacturing the same. The implementations and examples can be used to substantially address one or more technical or engineering issues and mitigate limitations or disadvantages encountered in some image sensing devices in the art. Some implementations of the disclosed technology suggest examples of a method for preventing light reflected from a module or portion of an image sensing device from being introduced into an effective pixel region of the image sensing device. The disclosed technology provides various implementations of the image sensing device that can prevent undesired light reflected from a module or portion of an image sensing device from being introduced into an effective pixel region.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

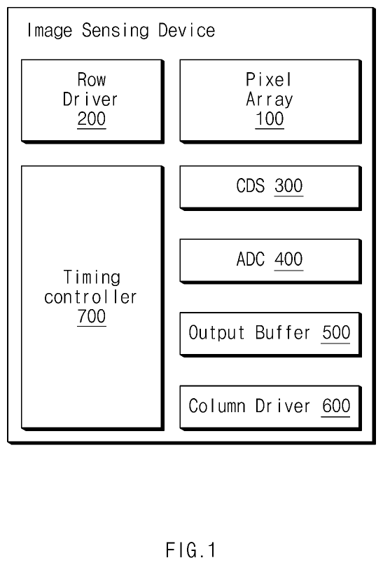

FIG. 1 is a block diagram illustrating an image sensing device based on some implementations of the disclosed technology.

Referring to FIG. 1, the image sensing device may include a pixel array 100, a row driver 200, a correlated double sampler (CDS) 300, an analog-to-digital converter (ADC) 400, an output buffer 500, a column driver 600 and a timing controller 700. The components of the image sensing device illustrated in FIG. 1 are discussed by way of example only, and this patent document encompasses numerous other changes, substitutions, variations, alterations, and modifications.

The pixel array 100 may include a plurality of unit pixels arranged in rows and columns. The pixel array 100 may include an effective pixel region having effective pixels, each of which generates an electrical signal (pixel signal) required for image formation through photoelectric conversion of incident light received from the outside, and may further include a dummy region having dummy pixels while being disposed outside the effective pixel region. In addition, the pixel array 100 may include a flare protection wall disposed in a boundary region between the effective pixel region and the dummy region.

The pixel array 100 may receive driving signals (for example, a row selection signal, a reset signal, a transmission (or transfer) signal, etc.) from the row driver 200. Upon receiving the driving signal, the unit pixels may be activated to perform the operations corresponding to the row selection signal, the reset signal, and the transfer signal.

The row driver 200 may activate the pixel array 100 to perform certain operations on the unit pixels in the corresponding row based on control signals provided by controller circuitry such as the timing controller 700.

The correlated double sampler (CDS) 300 may remove undesired offset values of the unit pixels using correlated double sampling. The CDS 300 may transfer the reference signal and the pixel signal of each of the columns as a correlate double sampling (CDS) signal to the ADC 400 based on control signals from the timing controller 700.

The ADC 400 is used to convert analog CDS signals received from the CDS 300 into digital signals.

The output buffer 500 may temporarily store column-based image data provided from the ADC 400 based on control signals of the timing controller 700.

The column driver 600 may select a column of the output buffer 500 upon receiving a control signal from the timing controller 700, and sequentially output the image data, which are temporarily stored in the selected column of the output buffer 500.

The timing controller 700 may generate signals for controlling operations of the row driver 200, the ADC 400, the output buffer 500 and the column driver 600.

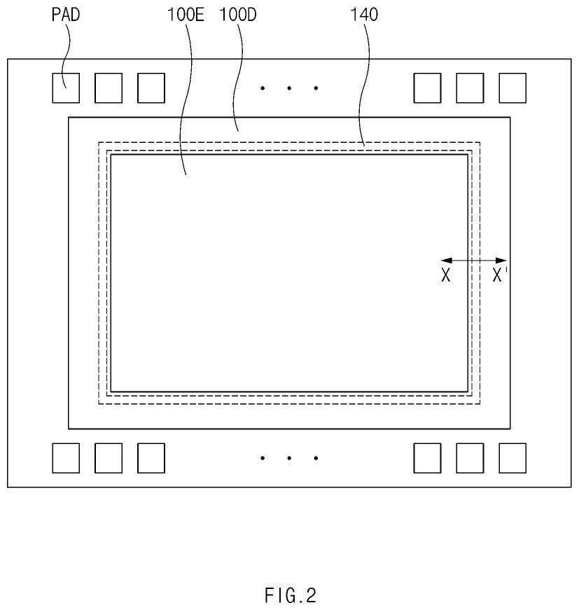

FIG. 2 is a schematic diagram illustrating an example of a planar structure of the pixel array 100 of FIG. 1 based on some implementations of the disclosed technology.

Referring to FIG. 2, the pixel array 100 may include an effective pixel region 100E and a dummy region 100D. In some implementations, the dummy region 100D is located along outer edges of the effective pixel region 100E and surrounds the effective pixel region 100E.

The effective pixel region 100E may be disposed in a rectangular shape at the center of the image sensing device. The effective pixel region 100E may include a plurality of effective pixels arranged in a two-dimensional (2D) matrix. The effective pixels are utilized to capture an image projected onto the image sensing device, for example, by sensing and converting light into electrical signals. The plurality of effective pixels may generate pixel signals through photoelectric conversion of incident light and the generated pixel signals are used for image formation. The plurality of effective pixels may include a plurality of red pixels, a plurality of green pixels, and/or a plurality of blue pixels. In the example, the plurality of red pixels, the plurality of green pixels, and the plurality of blue pixels may be arranged in an RGGB Bayer pattern.

The dummy region 100D may be located outside the effective pixel region 100E while being adjacent to the effective pixel region 100E. For example, the dummy region 100D may be located outside the effective pixel region 100E in a rectangular frame shape surrounding the effective pixel region 100E. The dummy region 100D may include a plurality of dummy pixels. The dummy pixels included in the dummy region 100D may be distinguished from the effective pixels in the effective pixel region 100E in terms of the operations as not being directly utilized for the image formation. The dummy pixels are designed and operated to compensate for undesired characteristics of the image sensing device and improve overall imaging operation of the image sensing device. The dummy region 100D may include a light shielding layer to block light from being introduced into a semiconductor substrate. The light shielding layer may include a metal layer (e.g., tungsten) and may be formed over the semiconductor substrate. In the dummy region 100D, a region where the light shielding layer is formed may include an optical black pixel region configured to generate a pixel signal in a dark state. The optical black pixel region may include black pixels that are shielded from light that is incident upon a surface of the image sensing device and can be used, for example, for noise correction, and so on

In some implementations, the dummy region 100D may include a flare protection wall 140 to block reflected light such that the reflected light does not introduce into the effective pixel region 100E. Thus, the flare protection wall 140 operates to reflect unwanted light that has been reflected from the image sensing device (e.g., any portion or module of the image sensing device). The flare protection wall 140 may be disposed in a region that is within the dummy region 100D and adjacent to the effective pixel region 100E. In some implementations, the flare protection wall 140 may be disposed in a boundary region between the effective pixel region 100E and the dummy region 100D. The flare protection wall 140 may be formed in a rectangular frame shape surrounding the effective pixel region 100E.

The flare protection wall 140 may be disposed over the light shielding layer of the dummy region 100D, and may extend upward from the light shielding layer by a predetermined height. For example, the flare protection wall 140 may be formed to penetrate a color filter layer, and may also be formed to have a predetermined height at which the flare protection wall 140 can extend to the inside of a lens layer. In some implementations, the flare protection wall 140 may be formed to have a predetermined height at which the flare protection wall 140 can penetrate the color filter layer and the lens layer.

The flare protection wall 140 may include a material layer having high reflectivity. For example, the flare protection wall 140 may include aluminum (Al). In some implementations, the flare protection wall 140 may include a non-metallic material having a higher refractive index than the lens layer 160. For example, the flare protection wall 140 may include a non-metallic material having a refractive index of 1.6 or greater.

A plurality of pads (PAD) may be formed outside the dummy region 100D.

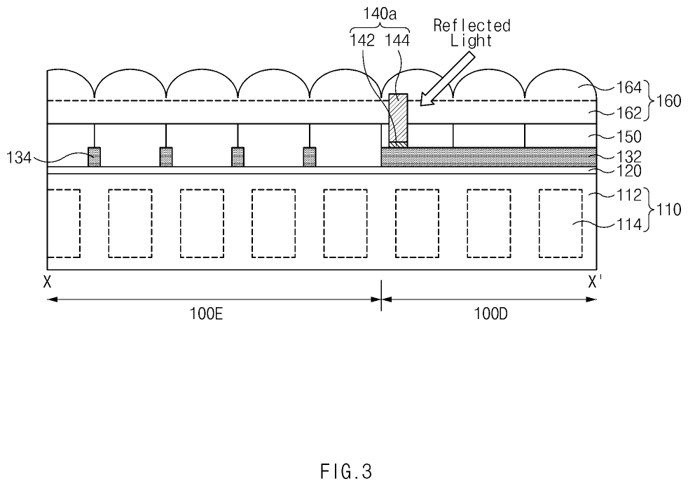

FIG. 3 is a cross-sectional view illustrating an example of the pixel array 100 taken along the line X-X′ shown in FIG. 2 based on some implementations of the disclosed technology.

Referring to FIG. 3, the pixel array 100 may include a substrate layer 110, an anti-reflection layer 120, a light shielding layer 132, a grid structure 134, a flare protection wall 140a, a color filter layer 150, and a lens layer 160.

The substrate layer 110 may include a substrate 112 and a plurality of photoelectric conversion regions 114. The substrate layer 110 may include a first surface and a second surface facing away from or opposite to the first surface. In this case, the first surface may refer to a light receiving surface upon which light is incident from the outside

The substrate 112 may include a semiconductor substrate including a monocrystalline silicon material. The substrate 112 may include P-type impurities.

The photoelectric conversion regions 114 may be formed in the semiconductor substrate 112 and each photoelectric conversion region 114 can correspond to each imaging pixel. The photoelectric conversion regions 114 may perform photoelectric conversion of incident light having penetrated the lens layer 160 and the color filter layer 150, and may generate photocharges that carry images in the incident light. Each of the photoelectric conversion regions 114 may include N-type impurities.

The anti-reflection layer 120 may be disposed over the first surface of the substrate layer 110, and may prevent reflection of light so that light incident upon the first surface of the substrate layer 110 can effectively reach the photoelectric conversion regions 114. For example, the anti-reflection layer 120 may compensate for a difference in refractive index among the substrate layer 110, the color filter layer 150 and the overcoating layer 162, and may thus enable light having penetrated the color filter layer 150 and the overcoating layer 162 to be effectively incident upon the substrate layer 110. The anti-reflection layer 120 may operate as a planarization layer to compensate for (or remove) a step difference that may be formed on the substrate layer 110. The anti-reflection layer 120 may include at least one of a silicon oxide layer, a silicon nitride layer, a silicon oxynitride layer, or a high-permittivity (high-K) layer (e.g., a hafnium oxide layer or an aluminum oxide layer).

In the example, the light shielding layer 132 may be formed in a flat plate shape on the substrate layer 110 in the dummy region 100D to block light from being introduced into the substrate layer 110. The light shielding layer 132 may include a metal layer such as tungsten (W). The photoelectric conversion regions disposed below the light shielding layer 132 may include photoelectric conversion regions of optical black pixels that generate pixel signals in a dark state without the incident light.

The grid structure 134 may be formed over the anti-reflection layer 120 in the effective pixel region 100E. The grid structure 134 formed in a grid shape may be disposed between the color filters to prevent crosstalk between adjacent color filters. The grid structure 134 may be formed of or include the same material as the light shielding layer 132. For example, the grid structure 134 may include a metal layer such as tungsten (W), and the grid structure 134 and the light shielding layer 132 may be simultaneously formed through the same process.

In the example, the flare protection wall 140a may be disposed on the light shielding layer 132 in the dummy region 100D and have a predetermined height. The flare protection wall 140a can prevent light reflected from a module or portion of the image sensing device from being introduced into the effective pixel region 100E. In the example, the flare protection wall 140a may have a barrier shape. For example, both sidewalls of the flare protection wall 140a may be formed in a vertical wall shape extending in a direction perpendicular to a top surface of the light shielding layer 132. In some implementations, one of sidewalls of the flare protection wall 140a may be inclined with respect to the top surface of the light shielding layer 132, while the inclination angle may be unequal to 90 degrees. The flare protection wall 140a may be formed to be adjacent to the effective pixel region 100E while being within in the dummy region 100D. For example, the flare protection wall 140a may be disposed in a boundary region between the effective pixel region 100E and the dummy region 100D. The flare protection wall 140 may be formed to penetrate a color filter layer, and may also be formed to have a predetermined height at which the flare protection wall 140 can extend to the inside of a lens layer. In some implementations, the flare protection wall 140 may be formed to have a predetermined height at which the flare protection wall 140 can penetrate the color filter layer 150 and the lens layer 160.

The flare protection wall 140a may include a material layer having a high reflectivity. For example, the flare protection wall 140 may include an aluminum (Al) layer. A barrier metal layer 142 may be formed between the aluminum (Al) layer 144 and the light shielding layer 132. The barrier metal layer 142 may include at least one of titanium (Ti) or titanium nitride (TiN). In some implementations, the flare protection wall 140a may include, for example, a non-metallic material having a higher refractive index than the lens layer 160.

The color filter layer 150 may filter visible light from light incident through the lens layer 160. The color filter layer 150 may include red color filters, green color filters, and blue color filters arranged in a Bayer pattern. The color filters may be formed in a region defined by the grid structure 134 on the anti-reflection layer 120 in the effective pixel region 100E, and may be formed to entirely cover the light shielding layer 132 in the dummy region 100D.

The lens layer 160 may include an overcoating layer 162 and a plurality of microlenses 164. The overcoating layer 162 may be formed to cover the color filter layer 150. The overcoating layer 162 may operate as a planarization layer to compensate for (or remove) a step difference caused by the color filter layer 150. The microlenses 164 may be formed over the overcoating layer 162. Each of the microlenses 164 may be formed in a convex lens shape, and may be formed for each unit pixel. The microlenses 164 may converge incident light, and may transmit the converged light to the corresponding photoelectric conversion elements 114 in the effective pixel region 100E. The lens layer 160 may be formed to extend to the dummy region 100D. The overcoating layer 162 and the microlenses 164 may be formed of or include the same materials. For example, the overcoating layer 162 and the microlenses 164 may be formed of or include a light transmissive photoresist material.

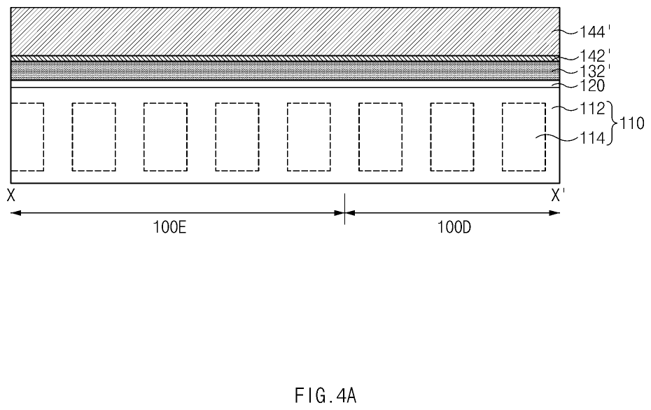

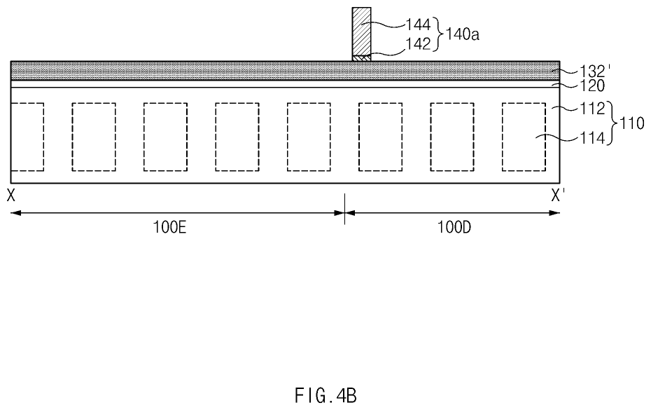

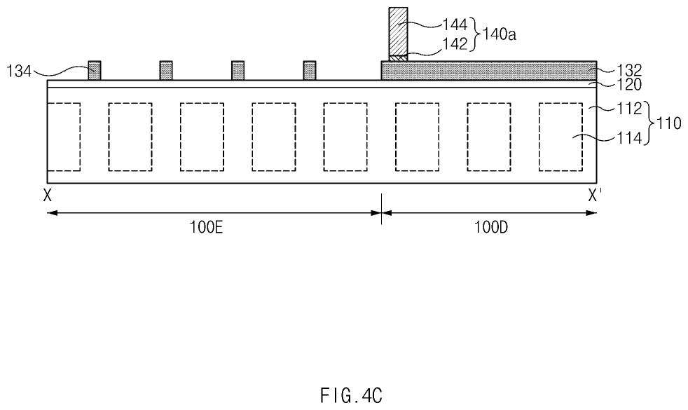

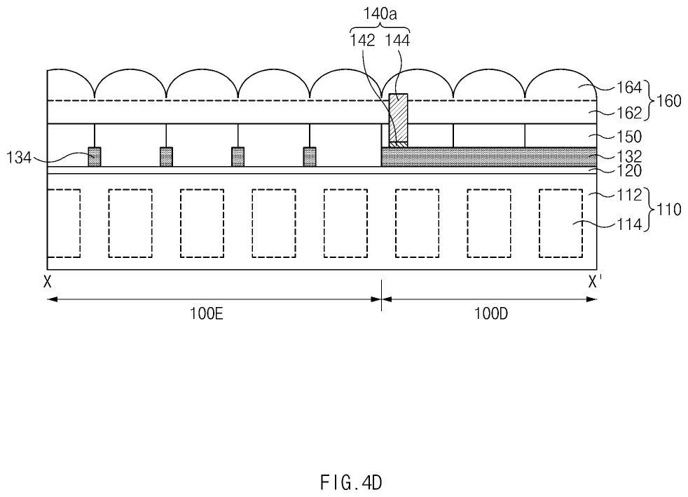

FIGS. 4A to 4D are cross-sectional views illustrating examples of methods for forming the structure shown in FIG. 3 based on some implementations of the disclosed technology.

Referring to FIG. 4A, an anti-reflection layer 120 and metal layers (132′, 142′, 144′) may be sequentially stacked over the substrate layer 110 including the photoelectric conversion regions 114. In this case, the anti-reflection layer 120 may include a silicon oxide layer, a silicon nitride layer, a silicon oxynitride layer, or a high-permittivity (high-K) layer (e.g., a hafnium oxide layer or an aluminum oxide layer). The metal layer 132′ may include tungsten (W), and the metal layer 142′ may include a barrier metal such as titanium (Ti) or titanium nitride (TiN). In some implementations, the metal layer 144′ may include aluminum (Al).

Referring to FIG. 4B, a flare protection wall 140a may be formed over the metal layer 132′ by patterning the metal layers (144′, 142′). For example, after a photoresist pattern (not shown) defining a region where the flare protection wall 140a is to be formed is formed over the metal layer 144′, the metal layers (144′, 142′) may be sequentially etched using the photoresist pattern as an etch mask, resulting in formation of the flare protection wall 140a in which the barrier metal layer 142 and the aluminum (Al) layer 144 are stacked.

Referring to FIG. 4C, the metal layer 132′ may be patterned to form the light shielding layer 132 and the grid structure 134.

For example, after a photoresist pattern (not shown) defining a region where the grid structure 134 and the light shielding layer 132 are to be formed is formed over the metal layer 132′, the metal layer 132′ may be etched using the photoresist pattern as an etch mask. As a result, the grid structure 134 may be formed in the effective pixel region 100E, and the light shielding layer 132 may be formed in the dummy region 100D.

Referring to FIG. 4D, the color filter layer 150 may be formed over the region defined by the grid structure 134 and the light shielding layer 132. The color filter layer 150 may include red color filters, green color filters, and blue color filters arranged in a Bayer pattern.

Subsequently, the overcoating layer 162 may be formed over the color filter layer 150. For example, the overcoating layer 162 may be formed such that a light transmissive photoresist material covers the color filters. The top surface of the overcoating layer 162 may be formed lower than the top surface of the flare protection wall 140a, and the top surface of the overcoating layer 162 can be planarized (or flattened).

Subsequently, the microlenses 164 may be formed over the overcoating layer 162. For example, after a photoresist pattern is formed over the overcoating layer 162 to correspond to each photoelectric conversion region 114, a reflow process is performed on the resultant photoresist pattern, resulting in formation of upwardly convex-shaped microlenses 164.

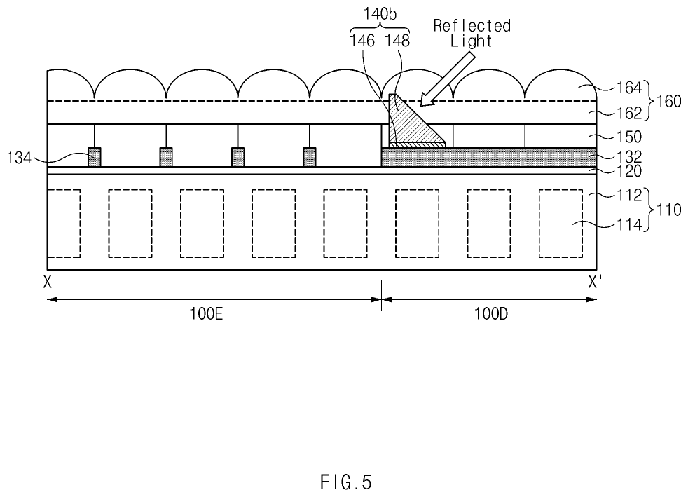

FIG. 5 is a cross-sectional view illustrating another example of the pixel array taken along the line X-X′ shown in FIG. 2 based on some implementations of the disclosed technology.

Referring to FIG. 5, while the flare protection wall 140b has both sidewalls, one of the sidewalls may be formed to be inclined. The reflected light may be incident upon the inclined sidewall of the flare protection wall 140b and such reflected light incident from the outside can be reflected without entering to the effective pixel region. For example, one sidewall of the flare protection wall 140b, which is adjacent to the effective pixel region 100E, may be formed to have a vertical wall shape extending in a direction perpendicular to the top surface of the light shielding layer 132, and the other sidewall of the flare protection wall 140b, which is located opposite to the one sidewall, may be formed to have an inclined shape.

The flare protection wall 140b may include a stacked structure of a barrier metal layer 146 and the aluminum layer 148. The barrier metal layer 146 may include at least one of titanium (Ti) and titanium nitride (TiN).

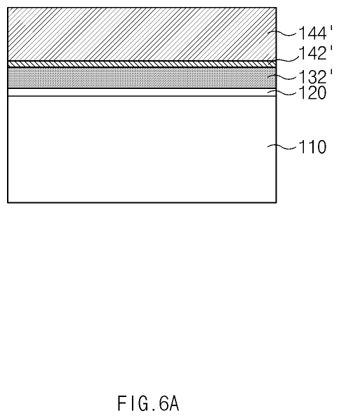

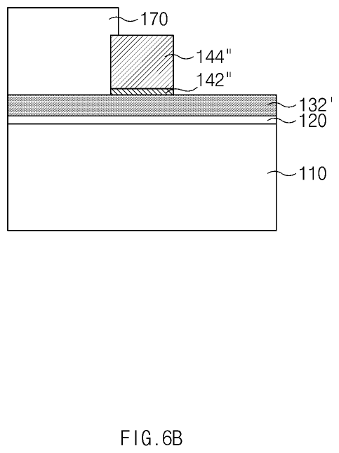

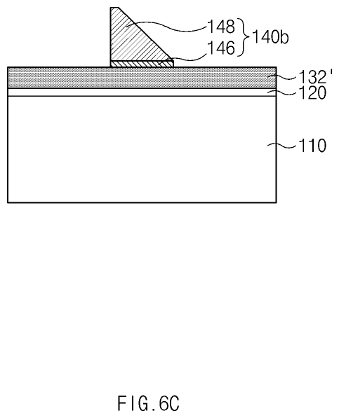

FIGS. 6A to 6C are cross-sectional views examples of a method for forming the flare protection wall having the same shape as in FIG. 5 based on some implementations of the disclosed technology. In the present embodiment, only a method for forming the flare protection wall 140b will hereinafter be described with reference to FIGS. 6A to 6C.

Referring to FIG. 6A, the anti-reflection layer 120 and the metal layers (132′, 142′, 144′) may be sequentially formed over the substrate layer 110. In this case, the anti-reflection layer 120 may include a silicon oxide layer, a silicon nitride layer, a silicon oxynitride layer, or a high-permittivity (high-K) layer (e.g., a hafnium oxide layer or an aluminum oxide layer). The metal layer 132′ may include tungsten (W), and the metal layer 142′ may include a barrier metal such as titanium (Ti) or titanium nitride (TiN). In addition, the metal layer 144′ may include aluminum (Al).

Referring to FIG. 6B, after the metal layers (144′, 142′) are patterned, a photoresist layer 170 may be formed to cover a portion corresponding to only one sidewall of the patterned metal layer patterns (144″, 142″).

Referring to FIG. 6C, the flare protection wall 140b is formed by performing an inclination etching on the metal layer patterns (144″, 142″). During the inclination etching, the metal layer patterns (144″, 142″) may be etched with a predetermined angle of inclination while one sidewall of each of the metal layer patterns (144″, 142″) is covered by the photoresist layer 170 and the other sidewall thereof is exposed outside.

The angle of the inclined surface may be adjusted to have a desired value by adjusting a critical dimension (CD) of the pattern during the inclination etching.

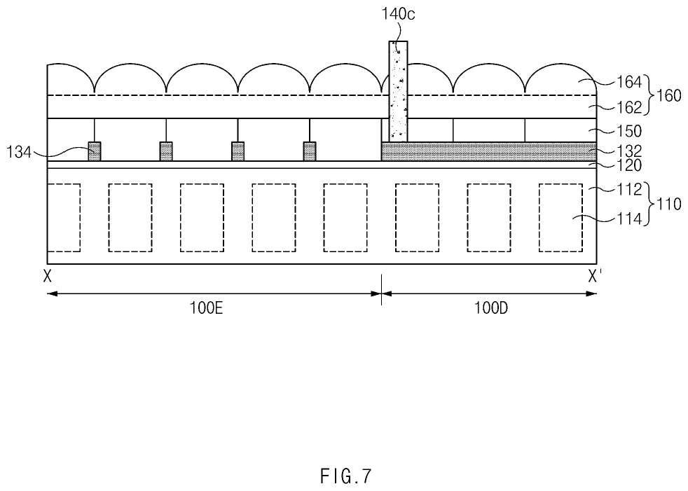

FIG. 7 is a cross-sectional view illustrating another example of the pixel array taken along the line X-X′ shown in FIG. 2 based on some implementations of the disclosed technology.

Referring to FIG. 7, an upper portion of the flare protection wall 140c may protrude upward from the lens layer 160. In some implementations, the flare protection wall 140c may include a non-metallic material having a higher refractive index than the lens layer 160. For example, the flare protection wall 140c may be formed of or include a non-metallic material having a refractive index of 1.6 or greater, and may include silicon nitride (SiN), silicon oxynitride (SiON), polysilicon, and the like.

Although the present embodiment has disclosed an example case in which the flare protection wall 140c formed of or including a non-metallic material is formed to protrude upward from the lens layer 160 for convenience of description, other implementations are also possible. For example, the flare protection walls (140a, 140b) of FIGS. 3 and 5 may also be formed such that the upper portion of each flare protection wall can be formed to protrude upward from the lens layer 160.

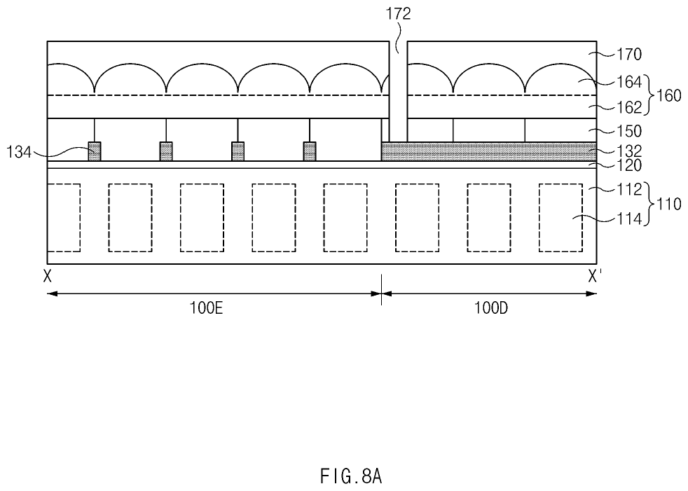

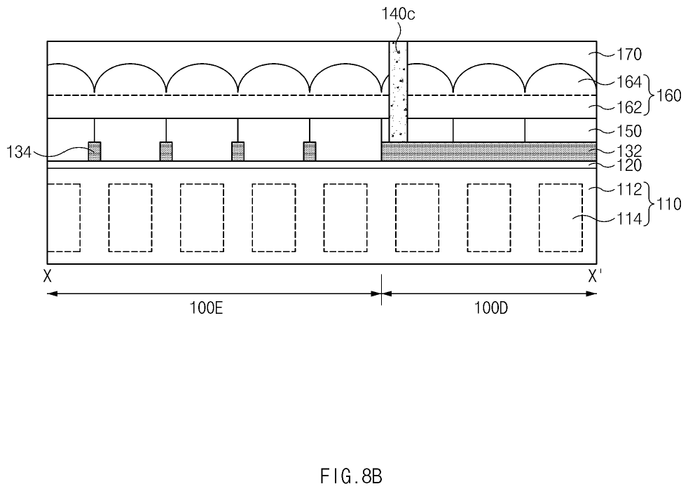

FIGS. 8A and 8B are cross-sectional views illustrating examples of a method for forming the structure shown in FIG. 7 based on some implementations of the disclosed technology.

Referring to FIG. 8A, the anti-reflection layer 120, the light shielding layer 132, the grid structure 134, the color filter layer 150 and the lens layer 160 may be formed over the substrate layer 110. For convenience of description, among various methods for forming the anti-reflection layer 120, the light shielding layer 132, the grid structure 134, the color filter layer 150 and the lens layer 160, any one of the methods can be used as an example, and as such a detailed description thereof will herein be omitted.

Subsequently, a photoresist pattern 170 defining a region where the flare protection wall 140c is to be formed may be formed over the microlenses 164. For example, a photoresist pattern 170 defining a frame-shaped region surrounding the effective pixel region 100E may be formed in a boundary region between the effective pixel region 100E and the dummy region 100D.

Thereafter, the lens layer 160 and the color filter layer 150 may be etched using the photoresist pattern 170 as an etch mask until the light shielding layer 132 is exposed outside, so that a trench 172 surrounding the effective pixel region 100E in a frame shape can be formed in the dummy region 100D.

Referring to FIG. 8B, the trench 172 may be filled with a non-metallic material, resulting in formation of the flare protection wall 140c. For example, the flare protection wall 140c may be formed by filling the trench 172 with a non-metallic material having a higher refractive index (e.g., a refractive index of 1.6 or greater) than the lens layer 160.

Thereafter, the photoresist pattern 170 can be removed.

As is apparent from the above description, the image sensing device and the method for manufacturing the image sensing device based on some implementations of the disclosed technology can prevent undesired light reflected from a module or portion of an image sensing device from being introduced into an effective pixel region.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a substrate layer configured to include an image pixel region including image pixels including photoelectric conversion elements configured to produce image pixel signals by a photoelectric conversion of incident light and a dummy region disposed separately from the image pixel region;
a first light shielding structure configured to cover the substrate layer of the dummy region and configured to block the incident light from being incident upon the substrate layer of the dummy region;
a color filter layer disposed over the first light shielding structure; and
a second light shielding structure configured to block reflected light from entering the image pixel region and disposed over the first light shielding structure, the second light shielding structure extending from the first light shielding structure toward the color filter layer and having a predetermined height that allows the second light shielding structure to penetrate the color filter layer.

2. The image sensing device according to claim 1, wherein:
the second light shielding structure is formed in a rectangular shape surrounding the image pixel region.

3. The image sensing device according to claim 1, wherein:
the second light shielding structure is disposed in a boundary region between the image pixel region and the dummy region.

4. The image sensing device according to claim 1, wherein:
the second light shielding structure has sidewalls perpendicular to a top surface of the first light shielding structure.

5. The image sensing device according to claim 1, wherein:
the second light shielding structure is configured to block the reflected light that is reflected from the image sensing device and has an inclined sidewall upon which the reflected light is incident.

6. The image sensing device according to claim 1, wherein:
the second light shielding structure includes a metal layer including a different material from that of the first light shielding structure.

7. The image sensing device according to claim 6, wherein:
the metal layer includes aluminum (Al).

8. The image sensing device according to claim 7, wherein the second light shielding structure further includes:
a barrier metal layer disposed between the metal layer and the first light shielding structure.

9. The image sensing device according to claim 1, wherein:
the second light shielding structure includes a non-metallic material having a refractive index that is equal to or greater than 1.6.

10. The image sensing device according to claim 1, further comprising:
a lens layer disposed over the color filter layer,
wherein the second light shielding structure extends to an inner region of the lens layer.

11. The image sensing device according to claim 10, wherein:
the lens layer includes an overcoating layer and a plurality of microlenses disposed over the overcoating layer; and
the second light shielding structure extends to inner regions of the plurality of microlenses while penetrating the overcoating layer.

12. The image sensing device according to claim 1, further comprising:
a lens layer disposed over the color filter layer,
wherein the second light shielding structure extends to penetrate the lens layer.

13. A method for manufacturing an image sensing device comprising:
forming a substrate layer to include 1) an image pixel region including image pixels including photoelectric conversion elements configured to produce image pixel signals by a photoelectric conversion of incident light and 2) a dummy region surrounding the image pixel region;
forming a first metal layer and a second metal layer over the substrate layer;
forming a second light shielding structure in a boundary region between the image pixel region and the dummy region by patterning the second metal layer;
patterning the first metal layer to form a grid structure in the image pixel region, and forming a first light shielding structure in the dummy region;
forming a color filter layer over a region defined by the grid structure and over the first light shielding structure; and
forming a lens layer over the color filter layer.

14. The method according to claim 13, further comprising:
forming a barrier metal layer between the first metal layer and the second metal layer.

15. The method according to claim 14, wherein the forming the second light shielding structure includes:
sequentially patterning the second metal layer and the barrier metal layer.

16. The method according to claim 13, wherein the forming the color filter layer includes:
forming the color filter layer such that an upper portion of the second light shielding structure protrudes upward from a top surface of the color filter layer.

17. The method according to claim 16, wherein the forming the lens layer includes:
forming the lens layer such that a top surface of the lens layer is located higher than a top surface of the second light shielding structure.

18. The method according to claim 16, wherein the forming the lens layer includes:
forming the lens layer such that the upper portion of the second light shielding structure protrudes upward from a top surface of the lens layer.

19. A method for manufacturing an image sensing device comprising:
forming a substrate layer to include 1) an image pixel region including image pixels including photoelectric conversion elements configured to produce image pixel signals by a photoelectric conversion of incident light and 2) a dummy region surrounding the image pixel region;
forming a metal layer over the substrate layer;
patterning the metal layer to form a grid structure in the image pixel region, and forming a first light shielding structure in the dummy region;
forming a color filter layer over a region defined by the grid structure and over the first light shielding structure;
forming a lens layer over the color filter layer;
forming a trench by etching the lens layer and the color filter layer to expose the first light shielding structure; and
forming a second light shielding structure by filling the trench with a light shielding material.

20. The method according to claim 19, wherein the forming the second light shielding structure includes:
filling the trench with a non-metallic material having a higher refractive index than that of the lens layer.
